(19) United States
(12) Patent Application Publication
(10) Pub. No.: US 2019/0306971 A1
(43) Pub. Date: Oct. 3, 2019

(54) CIRCUIT BOARD AND MANUFACTURING METHOD THEREOF

(71) Applicant: FANUC CORPORATION, Yamanashi (JP)

(72) Inventors: Norihiro SAIDO, Yamanashi (JP); Yutaka YAMADA, Yamanashi (JP)

(73) Assignee: FANUC CORPORATION, Yamanashi (JP)

(21) Appl. No.: 16/282,133

(22) Filed: Feb. 21, 2019

(30) Foreign Application Priority Data
Mar. 29, 2018 (JP) 2018-063751

(51) Int. Cl. H05K 1/02; H05K 1/14; H05K 3/36

(52) U.S. Cl. CPC H05K 1/0266; H05K 3/368; H05K 1/144; H05K 1/141

(57) ABSTRACT

A circuit board is obtained by forming a wiring pattern on an insulating member. The circuit board includes a first circuit board and a second circuit board. The first circuit board is obtained by providing a first wiring pattern on a first insulating board. The first wiring pattern has a first thickness which falls within a range from the maximum allowable thickness to the minimum allowable thickness. The second circuit board is obtained by providing a second wiring pattern on a second insulating board. The second wiring pattern has a second thickness which is thinner than the minimum allowable thickness of the first wiring pattern.

This application is based on and claims the benefit of priority from Japanese Patent Application No. 2018-063751, filed on Mar. 29, 2018, the content of which is incorporated herein by reference.

### BACKGROUND OF THE INVENTION

### Field of the Invention

The present invention relates to a circuit board and a method of manufacturing it.

### Related Art

Conventionally, under an environment in which a machine tool is used, a cutting fluid is converted into mist so as to be adhered to a circuit board within an electrical/electronic device. Hence, a wiring pattern is corroded (electrolytically corroded) so as to be broken, and thus a failure occurs in the device. The cause of electrolytic corrosion of a wiring pattern is not limited to a cutting fluid, and the electrolytic corrosion may be caused by humidity (water). In order to prevent the failure caused by the electrolytic corrosion or the corrosion of the wiring pattern as described above, various methods of detecting degradation of a circuit board are proposed.

As one method, there is a technology in which a degradation detection pattern having a structure that is degraded more easily than a normal wiring pattern is provided in a circuit board. For example, patent document 1 discloses a circuit board where a pattern in which the width of a conductor is narrower than the other wiring patterns is provided and a circuit board where a pattern in which an insulation distance between conductors is narrower than them is provided.
Patent Document 1: Japanese Patent No. 3952660

### SUMMARY OF THE INVENTION

However, the pattern in which the width of a conductor is narrower than the other wiring patterns or the pattern in which an insulation distance between conductors is narrower than them is present, and thus the yield in the manufacturing process of the circuit board is decreased.

The present invention is made in view of the foregoing problem, and an object of the present invention is to provide a circuit board which can reduce a decrease in yield and which can detect degradation and a method of manufacturing such a circuit board.

(1) The present invention relates to a circuit board (for example, a circuit board 10 which will be described later) in which a wiring pattern is provided on an insulating member, and in which the wiring pattern includes: a first wiring pattern (for example, a first wiring pattern 111 which will be described later) which has a first thickness (for example, a first thickness T1 which will be described later) that falls within a range from the maximum allowable thickness (for example, the maximum allowable thickness T11 which will be described later) to the minimum allowable thickness (for example, the minimum allowable thickness T12 which will be described later); and a second wiring pattern (for example, a second wiring pattern 121 which will be described later) which has a second thickness (for example, a second thickness T2 which will be described later) that is thinner than the minimum allowable thickness.

(2) Preferably, in the circuit board of (1), in the second wiring pattern, the width (for example, a width W2 which will be described later) of conductors (for example, conductors 122 which will be described later) of the second wiring pattern is substantially the same as the width (for example, a width w1 which will be described later) of conductors (for example, conductors 112 which will be described later) of the first wiring pattern, and the magnitude (for example, the magnitude G2 of a distance which will be described later) of a distance between the conductors of the second wiring pattern is substantially the same as the magnitude (for example, the magnitude G1 of a distance which will be described later) of a distance between the conductors of the first wiring pattern.

(3) Preferably, the circuit board of (1) or (2) includes: a first circuit board (for example, a first circuit board 11 which will be described later) in which the first wiring pattern is provided on a first insulating board (for example, a first insulating board 110 which will be described later); and a separate circuit member (for example, a second circuit board 12 which will be described later) in which the second wiring pattern is provided on a separate insulating member (for example, a second insulating board 120 which will be described later), which is separate from the first circuit board and which is connected to the first circuit board.

(4) The present invention relates to a method of manufacturing a circuit board which includes: a step (for example, a first board production step S11) of forming, on a first insulating board, a first wiring pattern which has a first thickness that falls within a range from the maximum allowable thickness to the minimum allowable thickness so as to produce a first circuit board; a step (for example, a second board production step S12 which will be described later) of forming, on a separate insulating member, a second wiring pattern which has a second thickness that is thinner than the minimum allowable thickness so as to produce a separate circuit member; and a step (for example, a board connection step S13 which will be described later) of connecting the separate circuit member to the first circuit board.

According to the present invention, an object is to provide a circuit board which can reduce a decrease in yield and which can detect degradation and a method of manufacturing such a circuit board.

### BRIEF DESCRIPTION OF THE DRAWINGS

FIG. 1 is a plan view of a circuit board according to an embodiment of the present invention;

FIG. 2 is a side cross-sectional view of the circuit board shown in FIG. 1;

FIG. 3A is a side cross-sectional view of a first circuit board in the circuit board shown in FIG. 1;

FIG. 3B is a side cross-sectional view of a second circuit board in the circuit board shown in FIG. 1;

FIG. 4 is a cross-sectional view showing a relationship between the first thickness of a first wiring pattern and the second thickness of a second wiring pattern; and

FIG. 5 is a flowchart illustrating a method of manufacturing the circuit board shown in FIG. 1.

### DETAILED DESCRIPTION OF THE INVENTION

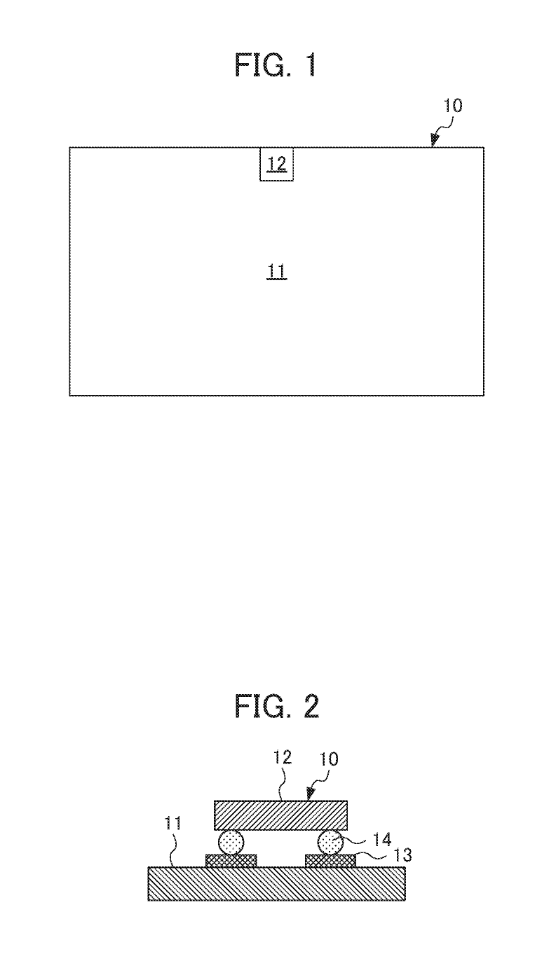

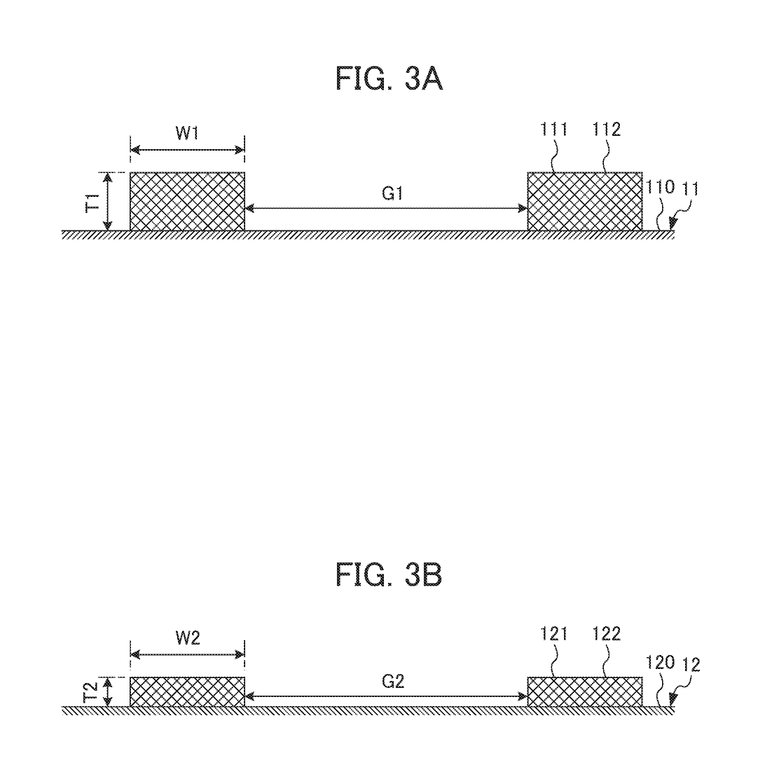

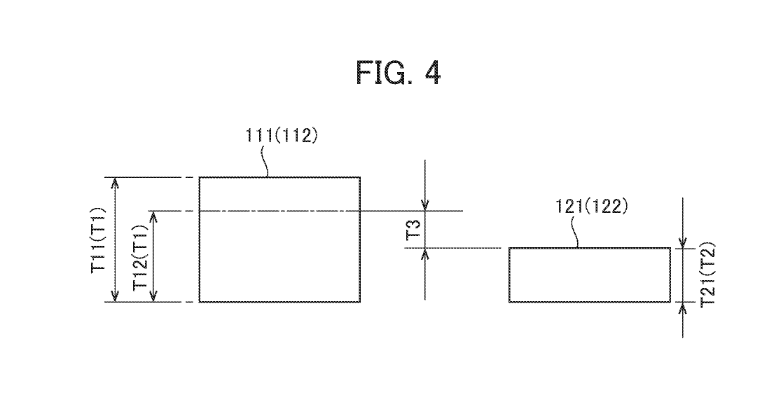

A circuit board according to an embodiment of the present invention will be described below with reference to drawings. The configuration of the circuit board 10 will first be described with reference to FIGS. 1 to 4. FIG. 1 is a plan view of the circuit board 10. FIG. 2 is a side cross-sectional view of the circuit board 10. FIG. 3A is a side cross-sectional view of a first circuit board 11 in the circuit board 10. FIG. 3B is a side cross-sectional view of a second circuit board 12 in the circuit board 10. FIG. 4 is a cross-sectional view showing a relationship between the first thickness of a first wiring pattern and the second thickness of a second wiring pattern.

As shown in FIGS. 1 and 2, the circuit board 10 is a board on which a wiring pattern is provided, and is applied to a machine tool, a robot controller or the like. An insulating board on which the wiring pattern is provided is a board that has insulation properties, and is not limited as long as a wiring pattern is provided on an insulating board such that a circuit board can be formed. As a typical example of the insulating board, c which is mainly formed of resin is mentioned. As another example, a ceramic board which is mainly formed of ceramic is mentioned. The circuit board 10 includes the first circuit board 11, the second circuit board 12 which serves as a separate circuit member, a pad 13 and a solder joint portion 14.

As shown in FIG. 3A, the first circuit board 11 is obtained by providing a first wiring pattern 111 on a first insulating board 110. As shown in FIGS. 3A and 4, the first wiring pattern 111 is formed with conductors 112 which have a first thickness T1 that falls within a range from a maximum allowable thickness T11 to a minimum allowable thickness T12. For example, the “maximum allowable thickness T11” and the “minimum allowable thickness T12” are respectively an upper limit value and a lower limit value in the manufacturing tolerance of the thickness. In FIG. 3A, W1 represents the width of the conductors 112, and G1 represents the magnitude of a distance between the conductors 112. As shown in FIG. 1, the outside shape of the first circuit board 11 agrees with the outside shape of the circuit board 10 in plan view.

As shown in FIG. 3B, the second circuit board 12 is obtained by providing a second wiring pattern 121 on a second insulating board 120 serving as a separate insulating member. As shown in FIGS. 3B and 4, the second wiring pattern 121 has a second thickness T2 (whose upper limit value is represented by T21) which is thinner than the minimum allowable thickness T12 of the first wiring pattern 111. A difference T3 between the minimum allowable thickness T12 of the first thickness T1 of the first wiring pattern 111 and the upper limit value T21 of the second thickness T2 of the second wiring pattern 121 is preferably a difference large enough to significantly identify a difference between both the thicknesses even with consideration given to the manufacturing tolerance of the thickness of the wiring pattern.

The conductor of a wiring pattern generally has a copper foil layer and a plating layer in the direction of the thickness. When the thickness of the conductor is changed, the thickness of the copper foil layer may be changed, the thickness of the plating layer may be changed or the thicknesses of both thereof may be changed.

As shown in FIGS. 3A and 3B, in the second wiring pattern 121, the width W2 of the conductors 122 of the second wiring pattern 121 is substantially the same as the width w1 of the conductors 112 of the first wiring pattern 111, and the magnitude G2 of the distance between the conductors 122 of the second wiring pattern 121 is substantially the same as the magnitude G1 of the distance between the conductors 112 of the first wiring pattern 111 (G2≈G1). The “substantially the same” here is said to be regarded as the same in a range for achieving the effects of the embodiment of the present invention, and they may differ in the range.

As shown in FIG. 1, the second circuit board 12 is located inward of a corner portion of the circuit board 10 in plan view. As long as the first circuit board 11 and the second circuit board 12 are connected to each other, the position of the second circuit board 12 is not limited to the position described above.

On the second circuit board 12, the second wiring pattern 121 which serves as a degradation detection pattern is preferably arranged in a position to which oil mist derived from a cutting fluid is easily adhered.

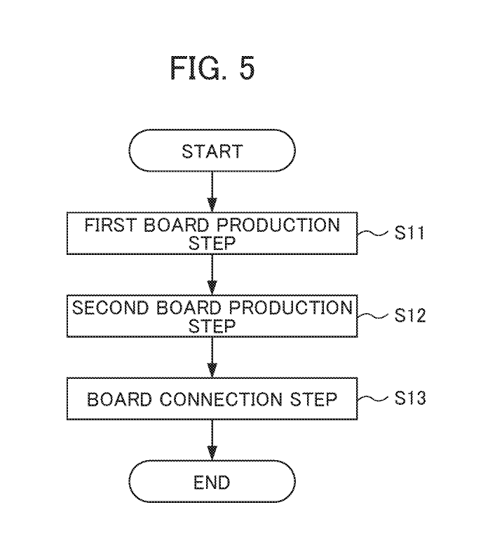

A method of manufacturing the circuit board 10 will then be described with reference to FIG. 5. FIG. 5 is a flowchart illustrating the method of manufacturing the circuit board 10 shown in FIG. 1.

As shown in FIG. 5, the method of manufacturing the circuit board 10 (see FIGS. 1 to 4) includes a first board production step S11, a second board production step S12 and a board connection step S13.

The first board production step S11 is a step of forming the first wiring pattern 111 on the first insulating board 110 so as to produce the first circuit board 11.

The second board production step S12 is a step of forming the second wiring pattern 121 on the second insulating board 120 so as to produce the second circuit board 12.

The board connection step S13 is a step of connecting the second circuit board 12 to the first circuit board 11 with the pad 13 and the solder joint portion 14. The steps S11 to S13 described above are performed so as to complete the circuit board 10.

For example, effects below are achieved by the circuit board 10 of the present embodiment. The circuit board 10 of the present embodiment is the circuit board 10 in which the wiring pattern is provided on the insulating board, and the wiring pattern includes: the first wiring pattern 111 which has the first thickness T1 that falls within the range between the maximum allowable thickness T11 and the minimum allowable thickness T12; and the second wiring pattern 121 which has the second thickness T2 that is thinner than the minimum allowable thickness T12.

Hence, the second wiring pattern 121 of the second circuit board 12 is used as the degradation detection pattern, and thus it is possible to detect degradation without provision of a pattern in which the width of conductors is narrower than the other wiring patterns or a pattern in which the insulation distance between conductors is narrower than them. Hence, as compared with a case where the pattern in which the width of conductors is narrower than the other wiring patterns is provided and a case where the pattern in which the insulation distance between conductors is narrower than them is provided, the structure of the wiring is simple, and thus it is possible to reduce a decrease in yield.

In the second wiring pattern 121 on the circuit board 10 of the present embodiment, the width W2 of the conductors 122 of the second wiring pattern 121 is substantially the same as the width w1 of the conductors 112 of the first wiring pattern 111, and the magnitude G2 of the distance between the conductors 122 of the second wiring pattern 121 is substantially the same as the magnitude G1 of the distance between the conductors 112 of the first wiring pattern 111. Hence, a difference between the first wiring pattern 111 and the second wiring pattern 121 is mainly the difference between the thicknesses. Hence, degradation can be detected mainly based on the difference between the thicknesses.

The circuit board 10 of the present embodiment includes: the first circuit board 11 in which the first wiring pattern 111 is provided on the first insulating board 110; and the second circuit board 12 in which the second wiring pattern 121 is provided on the first insulating board 110, which is separate from the first circuit board 11 and which is connected to the first circuit board 11. Hence, without masking for changing the thicknesses being performed, it is possible to easily produce the second wiring pattern 121 whose thickness is different from that of the first wiring pattern 111.

The present invention is not limited to the embodiment described above, and various modifications and variations are possible. For example, although in the embodiment described above, the second circuit board 12 is connected to the first circuit board 11 with the pad 13 and the solder joint portion 14, there is no limitation to this configuration. A region in which the second wiring pattern 121 is formed is covered with a masking tape (such as a film), and after the first wiring pattern 111 is formed, in which the first wiring pattern 111 is formed is covered with a masking tape (such as a film) and thus the second wiring pattern 121 whose thickness is different from that of the first wiring pattern 111 can be formed.

Although in the embodiment, the separate circuit board is obtained by providing the second wiring pattern 121 on the second insulating board 120, there is no limitation to this configuration. The separate circuit board may be obtained by providing the second wiring pattern on an insulating member (for example, a member whose thickness is large or a member having a block shape) which serves as a separate insulating member and which does not have a plate shape. The description on the insulating board discussed above is also applied to the separate insulating member.

### EXPLANATION OF REFERENCE NUMERALS

10 circuit board
11 first circuit board
110 first insulating board
111 first wiring pattern
112 conductor
12 second circuit board (separate circuit member)
120 second insulating board (separate insulating member)
121 second wiring pattern
122 conductor
13 pad
14 solder joint portion
T1 first thickness
T11 maximum allowable thickness
T12 minimum allowable thickness
T2 second thickness
T21 upper limit value of second thickness
W1, W2 width
G1, G2 magnitude of distance

What is claimed is:

1. A circuit board in which a wiring pattern is provided on an insulating member,
wherein the wiring pattern includes: a first wiring pattern which has a first thickness that falls within a range from a maximum allowable thickness to a minimum allowable thickness; and a second wiring pattern which has a second thickness that is thinner than the minimum allowable thickness.

2. The circuit board according to claim 1, wherein in the second wiring pattern, a width of conductors of the second wiring pattern is substantially the same as a width of conductors of the first wiring pattern, and a magnitude of a distance between the conductors of the second wiring pattern is substantially the same as a magnitude of a distance between the conductors of the first wiring pattern.

3. The circuit board according to claim 1, comprising: a first circuit board in which the first wiring pattern is provided on a first insulating board; and a separate circuit member in which the second wiring pattern is provided on a separate insulating member, which is separate from the first circuit board and which is connected to the first circuit board.

4. A method of manufacturing a circuit board comprising: a step of forming, on a first insulating board, a first wiring pattern which has a first thickness that falls within a range from a maximum allowable thickness to a minimum allowable thickness so as to produce a first circuit board;
a step of forming, on a separate insulating member, a second wiring pattern which has a second thickness that is thinner than the minimum allowable thickness so as to produce a separate circuit member; and
a step of connecting the separate circuit member to the first circuit board.
